(19) United States
(12) Patent Application Publication
(10) Pub. No.: US 2015/0295110 A1
(43) Pub. Date: Oct. 15, 2015

(54) THIN-LAYER PHOTOVOLTAIC DEVICE, IN PARTICULAR FOR SOLAR GLAZING

(71) Applicant: CROSSLUX, Rousset (FR)

(72) Inventors: Marc Ricci, Marseille (FR); Pierre-Yves Thoulon, Le Tholonet (FR); Ivan Jager, Aix En Provence (FR)

(73) Assignee: CROSSLUX, Rousset (FR)

(21) Appl. No.: 14/437,691

(22) PCT Filed: Oct. 22, 2013
(86) PCT No.: PCT/FR2013/052522

§ 371 Date: Apr. 22, 2015

(30) Foreign Application Priority Data
Oct. 23, 2012 (FR) 12/60071

(51) Int. Cl. H01L 31/0468; H01L 31/02

(52) U.S. Cl. CPC H01L 31/0468; H01L 31/02008

(57) ABSTRACT

Thin-film photovoltaic device (1) comprising a substrate on which is deposited a photovoltaic film (3) comprising a first conductive layer forming a back electrical contact, a second photoactive layer that is absorbent in the solar spectrum and that is based on an inorganic material, and a third layer made of a transparent conductive material forming a front electrical contact, said photovoltaic film being divided to form a plurality of individual and interconnected photovoltaic cells (30), wherein it comprises a plurality of individual holes (31) at least passing through the first and second layers of the photovoltaic film in each cell, each hole having dimensions in the principle plane comprised between 10 nanometres and 400 microns, each hole being separated from the closest adjacent hole by a distance comprised between 5 nanometres and 400 microns, and each cell having an apertured area, corresponding to the area of the holes arranged in said cell in the principle plane, comprised between 10 and 90% of the total area of the cell in said principle plane, and preferably between 30 and 70%. The present invention is applicable to the field of solar glazing units.

### TECHNICAL FIELD

The present invention relates to a thin-layer photovoltaic device.

More particularly, it relates to a thin-layer photovoltaic device comprising a substrate on which there is disposed a photovoltaic film composed of a superposition of layers distributed along a plane called main plane and comprising at least a first conductive layer forming a rear electrical contact, a second photoactive layer absorbing in the solar spectrum based on inorganic material, a third layer made of transparent conductive material forming a front electrical contact, said photovoltaic film being divided so as to form a plurality of individual and interconnected photovoltaic cells, each cell being connected in series or in parallel to one or several adjacent cell(s) and electrically insulated from the other adjacent cells.

### BACKGROUND

The photovoltaic device finds a particular application in the field of glazing called solar glazing or glazing called photovoltaic glazing, in which the substrate is constituted of a transparent glass substrate—or transparent glazing—with interconnected and more or less spaced photovoltaic cells so as to choose the best ratio between the luminosity or the overall transparency and the energy performance. The glazing may be of the double glazing or triple glazing type, in the form of laminated, insulating glazing, etc.

However, the present invention is not limited to such an application and other substrates may be considered with such a photovoltaic device, as for example a substrate made of organic material, a substrate made of plastic or polymers-based substrate, a substrate made of treated glass, for example of frosted, tinted, opaque glass, etc., a metallic substrate, a substrate made of construction material, for example of concrete, composite material, etc., optionally covered with a paint layer and/or a protective layer.

### BRIEF SUMMARY

The object of the present invention is to apply, over the substrate, a series of thin layers forming a photovoltaic film defining several interconnected photovoltaic cells which are shaped so as to let pass part of the light in order to confer to the photovoltaic film some transparency which ensures the visibility of a portion of the substrate. Thus, the photovoltaic film offers opaque areas and transparent areas which respectively allow hiding and exposing the substrate from the outside. In the following description, an area of the photovoltaic film is considered as transparent insofar as it easily lets light pass therethrough and clearly allows to distinguish the substrate through its thickness.

The integration of photovoltaic devices in a building is facing several constraints: the photovoltaic surface that may be used on a roof and/or a facade, the cost, the dimensions of the photovoltaic devices which should preferably be standardized in order to comply with the standards and usages in the field of construction, the installation of the photovoltaic devices with constraints of insulation, sealing, mechanical strength, wind resistance, etc. and the esthetics of the photovoltaic devices in particular in an integration on a facade.

To address these constraints, it is known to use photovoltaic devices called thin-layer or <<thin-film>> photovoltaic devices, using a photoactive layer absorbing in the solar spectrum, with a thickness ranging from a few atoms of thickness to about ten micrometers, made based on semi-conductive inorganic material, in particular based on Cu₂S/CdS, a-Si:H (hydrogenated amorphous silicon), CdTe (cadmium telluride), and CuInSe₂ (Copper Indium Selenium or CIS), CuInGaSe₂ (Copper Indium Gallium Selenium or CIGS).

These thin-layer photovoltaic devices based on inorganic materials belong to the second generation, after the first generation based on crystalline silicon, and before the third generation based on organic materials.

The organic photovoltaic materials are naturally transparent, however, they have limited lifespan, generally in the order of a few thousands of hours, and low electrical efficiencies or performances (efficiency in the order of 5 to 9% against 15 to 20% for the inorganic photovoltaic materials of the second generation), which are incompatible with an integration in a building.

The inorganic photovoltaic materials do not have intrinsic properties of transparency, and only the layout of the photovoltaic cells over the substrate will confer to the photovoltaic film a required transparency in order to be able to partly see the substrate through the film. Indeed, these inorganic photovoltaic materials have a very high light absorption level, for example, with absorption of 99% of the light reaching the surface of the CIGS material on the first micrometer of thickness. Thus, for the CIGS, a thickness of material that is larger than one micron leads to a layer that is opaque to light.

The present invention thus focuses on the layout of the photovoltaic cells made based on thin layers of inorganic photovoltaic material.

Generally, in a thin-layer photovoltaic device, the photovoltaic film is composed of a superposition of layers comprising a first conductive layer forming a rear electrical contact, a second photoactive layer absorbing in the solar spectrum and based on inorganic material, a third layer made of transparent conductive material forming a front electrical contact.

The third front contact layer may for example be constituted of a double-film layer of zinc oxide (ZnO) doped with elements of the group III such as aluminum, and it presents the highest possible luminous transmission in the range of wavelengths related to the second photoactive layer. It is known to use an intermediate thin layer, called window or <<buffer>> layer, between the second and the third layers, generally based on CdS (cadmium sulfide), ZnS, ZnSe, SnIn₂Se₄, Zn₁₋ₓMgₓO, In₂S₃, etc.

The second layer, called absorber, is made based on semi-conductive inorganic materials of the type I-III-VI, such as for example the CIGS, often referenced as chalcogenides materials.

The first layer is deposited over the substrate and has both ohmic properties to ensure an optimal recovery of the charges emitted by the second photoactive layer as well as optical properties to ensure reflection toward the second layer of the portion of the luminous spectrum that is not absorbed in direct transmission.

In the field of solar glazing based on thin layers of inorganic photovoltaic material, it is known to make the photovoltaic cells in the form of parallel opaque strips presenting a width in the order of centimeter and regularly spaced from each other with a spacing that is equivalent to the width of the strips; the cells being interconnected at their ends, the interconnections being generally hidden by the frame of the glazing.

Thus, the overall transparency of the glazing is in the order of 50%, but these photovoltaic strips, distributed in a linear array with a resolution in the order of centimeter, offer a real visual discomfort for the building users who look through the glazing.

The present invention aims to propose a thin-layer photovoltaic device comprising a substrate over which there is disposed a photovoltaic film based on semi-conductive inorganic material, of the second generation, with a control of the geometry of the photovoltaic cells which allow to obtain, at the same time, a film with a controlled transparency between 10 and 90% and a visual comfort resulting from a high resolution which provides the perception with a quasi-uniformity of the layout of the opaque layers.

To this end, it proposes a thin-layer photovoltaic device comprising a substrate on which there is disposed a photovoltaic film composed of a superposition of layers distributed along a plane called main plane and comprising at least a first conductive layer forming a rear electrical contact, a second photoactive layer absorbing in the solar spectrum based on inorganic material, a third layer made of transparent conductive material forming a front electrical contact, said photovoltaic film being divided to form a plurality of individual and interconnected photovoltaic cells, each cell being connected in series or in parallel with one or several adjacent cell(s) and electrically insulated from the other adjacent cells, wherein the device is remarkable in that it comprises a plurality of individual perforations passing through at least the first and the second layers of the photovoltaic film in each cell, each perforation presenting dimensions in the main plane comprised between 10 nanometers and 400 micrometers, each perforation being distant from the nearest adjacent perforation at a distance comprised between 5 nanometers and 400 micrometers, and in that each cell presents a perforated surface, corresponding to the surface of the perforations disposed in said cell in the main plane, which is comprised between 10 and 90% of the total surface of the cell in this same main plane, preferably between 30 and 70%.

Thus, the photovoltaic cells are perforated, at least over the thickness of the first and second layers (the third layer being transparent), and these perforations are distributed, in a quasi-uniform manner, in each cell with a resolution comprised between 5 nanometers and 400 micrometers, guaranteeing, for the human eye, a quasi-uniform perception of the outer surface of the film, with a controlled transparency of the film which ensures visibility of the support through the film.

Indeed, the resolving power of the eye (minimum distance that should exist between two contiguous points so that they are correctly discerned) is of about one minute of arc, namely 0.017°, which corresponds to a minimum distance of about 600 micrometers for an image located at a distance of 2 meters from the eye.

According to one characteristic, the perforations are distributed over the surface of each cell according to a non-periodic distribution, in particular according to a non-periodic paving.

The non-periodic distribution (in other words irregular distribution) of the perforations has the advantage of avoiding a periodic repetition of patterns which catches the eye and reduces the visual comfort. Thanks to such a non-periodic distribution, a person who looks through the device will be much less disturbed by the perforations in comparison with a periodic or regular distribution.

Advantageously, the perforations are distributed over the surface of each cell according to a random distribution, in particular according to a random paving. This random distribution, which is a particular case of the non-periodic distribution, is particularly advantageous for visual comfort through the device.

According to one characteristic, the perforations are distributed over the surface of each cell according to a periodic distribution, in particular according to a periodic paving. Such a periodic distribution being advantageous for simplifying the realization of the perforations, due to the regular repetition.

According to one characteristic, the perforations are distributed over the surface of each cell according to a virtual paving composed of a plurality of elementary photovoltaic units, juxtaposed without void and without encroachment so as to define the corresponding cell, each elementary unit being in the form of a geometric portion of the photovoltaic film delimited by a virtual outline and to which there is associated at least one perforation arranged in whole or in part inside said outline, each perforation being associated to one single elementary unit, and wherein each elementary unit presents a perforated surface, corresponding to the surface of the perforation(s) associated to said elementary unit in the main plane, which is comprised between 10 and 90% of the total surface of the elementary unit in this same main plane, preferably between 30 and 70%.

Thus, each photovoltaic cell is geometrically defined by a paving of elementary photovoltaic units and each one of these present units is perforated so as to intrinsically offer the desired overall transparency. In this manner, the macroscopic photovoltaic cell presents the same transparency as its own elementary units which compose it.

According to another characteristic, each elementary unit presents dimensions in the main plane comprised between 10 and 800 micrometers.

To make a non-periodic distribution (for example, but not only, random distribution) of the perforations, it may be considered to proceed with one of the following two solutions:

first solution: the elementary units are distributed over the surface of each cell according to a non-periodic paving, and the elementary units are identical in the shape and the dimensions of the virtual outline as well as in the conformation, the number and the dimensions of the perforation(s) associated to each elementary unit;

second solution: the elementary units are distributed over the surface of each cell according to a periodic paving, and the elementary units are identical in the shape and the dimensions of the virtual outline but distinct in the conformation, the number and/or the dimensions of the perforation(s) associated to each elementary unit.

With the first solution, we play on a non-periodic paving of the elementary units so as to obtain the non-periodic distribution of the perforations, whereas with the second solution, we play on the differences between the elementary units so as to obtain the non-periodic distribution of the perforations.

To make a periodic distribution of the perforations, it may be considered to proceed as follows: the elementary units are distributed over the surface of each cell according to a periodic paving, and the elementary units are identical in the shape and the dimensions of the virtual outline as well as in the conformation, the number and the dimensions of the perforation(s) associated to each elementary unit.

In a particular embodiment, the substrate is constituted of a glass substrate, so as to make a photovoltaic or solar glazing.

According to a particular embodiment, the first layer is an opaque metallic layer directly in contact over the substrate.

The present invention also relates to a method for manufacturing a photovoltaic device in accordance with the invention, wherein:

a photovoltaic film is disposed over a substrate by the superposition of layers distributed along a plane called main plane and comprising at least a first conductive layer forming a rear electrical contact, a second photoactive layer absorbing in the solar spectrum and based on inorganic material, and a third layer made of transparent conductive material forming a front electrical contact;

the photovoltaic film is divided into a plurality of individual and interconnected photovoltaic cells, each cell being connected in series or in parallel with one or several adjacent cell(s) and electrically insulated from the other adjacent cells,

said method being remarkable in that there is arranged a plurality of individual perforations passing through at least the first and second layers of the photovoltaic film in each cell, in compliance with the following geometric characteristics:

each perforation presents dimensions in the main plane comprised between 10 nanometers and 400 micrometers,

each perforation is distant from the nearest adjacent perforation by a distance comprised between 5 nanometers and 400 micrometers,

each cell presents a perforated surface, corresponding to the surface of the perforations disposed in said cell in the main plane, which is comprised between 10 and 90% of the total surface of the cell in this same main plane, preferably between 30 and 70%.

According to a first possibility, the perforations are distributed over the surface of each cell according to a non-periodic distribution, in particular according to a non-periodic paving. For example, the perforations are distributed over the surface of each cell according to a random distribution, in particular according to a random paving.

According to a second possibility, the perforations are distributed over the surface of each cell according to a periodic distribution, in particular according to a periodic paving.

According to one possibility of the invention, the sequence called main sequence is carried out, including the following steps:

a first conductive layer is made with through orifices disposed in accordance with the geometric characteristics of the perforations;

the second layer is deposited over the non-perforated portions of the first conductive layer, preferably by electrodeposition;

the third layer is deposited, preferably by evaporation.

The third transparent layer does not modify the transparency and thus may cover the bare areas of the substrate in the orifices passing through the first layer.

In a first embodiment, a first uniform conductive layer is deposited over the substrate then the through orifices are engraved in said first conductive layer, in particular by laser engraving.

In a second embodiment, a mask is deposited according to a printing method, in particular of the type material-jet digital printing, flexography, screen-printing or pad-printing, said mask presenting main areas defining a positive or a negative of the perforations made at least in the first layer.

The use of such a mask deposited by printing is really advantageous to obtain the desired resolutions in the distribution of perforations. Thanks to this printing technique (over the substrate, over a resin layer or over the first layer, as explained later), it is possible to make the paving of the aforementioned elementary units, with enough precision for guaranteeing the expected dimensions of the perforations as well as between the perforations.

It may be considered to provide for several modes of use of the mask.

According to a first use of the mask, the following first sequence is carried out:

a first uniform conductive layer is deposited over the substrate;

a photosensitive resin layer is deposited over the first uniform conductive layer;

the mask is deposited over the resin layer, said mask forming a positive stencil of the geometric conformation of the perforations;

the resin is insolated by applying a luminous radiation;

the areas of the resin layer that have not been exposed to the luminous radiation and corresponding to the areas of the resin layer that have been masked by the mask, are eliminated, laying bare areas of the first uniform conductive layer and leaving in place islets of insolated resin;

the areas of the first conductive layer that have been laid bare, between the islets of insolated resin, are eliminated, thereby forming through orifices in said first conductive layer;

the islets of insolated resin remaining on the first conductive layer are eliminated, thereby leaving over the substrate only but the first conductive layer presenting positive orifices of the mask.

Afterwards, the steps of the above-mentioned main sequence are resumed.

According to a second use of the mask, the following second sequence is carried out:

a photosensitive resin layer is deposited over the substrate;

the mask is deposited over the resin layer, said mask forming a negative stencil of the geometric conformation of the perforations;

the resin is insolated by applying a luminous radiation;

the areas of the resin layer that have not been exposed to the luminous radiation and corresponding to the areas of the resin layer that have been masked by the mask, are eliminated, laying bare areas of the substrate and leaving in place islets of insolated resin;

a first conductive layer, which covers the remaining islets of insolated resin and the areas of the substrate that have been laid bare, is deposited in a uniform manner.

Following this second sequence, two options may be considered.

In a first option, following the deposition of the first conductive layer, the remaining islets of insolated resin are eliminated, leaving over the substrate only but the first conductive layer presenting negative orifices of the mask. Afterwards, the steps of the above-mentioned main sequence are resumed.

In a second option, following the deposition of the first conductive layer:

the second layer, which covers the first conductive layer, is deposited in a uniform manner;

the third layer, which covers the second layer, is deposited in a uniform manner;

the remaining islets of insolated resin are eliminated, leaving over the substrate the photovoltaic film presenting negative perforations of the mask.

In this second option, the second and third layers are uniformly deposited, preferably by vaporization, and not in a selective manner as in the case of the first option.

According to a third use of the mask, the following sequence is carried out:

the mask is deposited over the substrate, said mask forming a positive stencil of the geometric conformation of the perforations;

a first conductive layer, which covers the mask and the bare areas of the substrate, is deposited in a uniform manner.

Thus, the mask is deposited directly over the substrate, and no longer on a resin layer as in the first and second uses. Following this sequence, two options may be considered.

In a first option, following the deposition of the first conductive layer, the mask is eliminated, leaving over the substrate only but the first conductive layer presenting positive orifices of the mask. Afterwards, the steps of the above-mentioned main sequence are resumed.

In a second option, following the deposition of the first conductive layer:

the second layer, which covers the first conductive layer, is deposited in a uniform manner;

the third layer, which covers the second layer, is deposited in a uniform manner;

the mask is eliminated, leaving over the substrate the photovoltaic film presenting positive perforations of the mask.

Advantageously, the mask presents secondary areas defining a positive or a negative of the separating strips between the cells.

Thus, the mask is advantageously utilized to directly prepare the separation between the photovoltaic cells.

### BRIEF DESCRIPTION OF THE DRAWINGS

Other characteristics and advantages of the present invention will appear upon reading the detailed description below, of several non-limiting implementation examples, with reference to the appended figures wherein:

FIG. 1a is a schematic front view of a photovoltaic device in accordance with the invention;

FIG. 1b is a schematic sectional view of the photovoltaic film of the device of FIG. 1a;

FIG. 2a is a schematic front view of a photovoltaic cell for a photovoltaic device in accordance with the invention;

FIG. 2b is a schematic front view of a photovoltaic device integrating several interconnected cells of the type illustrated in FIG. 2a;

FIG. 3 represents schematic partial-sectional views of a first sequence for making, over a substrate, a first conductive layer with through orifices (three steps 3a to 3c being illustrated);

FIG. 4 represents schematic partial-sectional views of a second sequence for making, over a substrate, a first conductive layer with through orifices (six steps 4a to 4f being illustrated);

FIG. 5 represents schematic partial-sectional views of a third sequence for making, over a substrate, a first conductive layer with through orifices (four steps 5a to 5d being illustrated);

FIG. 6 represents schematic partial-sectional views of a fourth sequence for making, over a substrate, a first conductive layer with through orifices (seven steps 6a to 6g being illustrated);

FIG. 7 represents schematic partial-sectional views of an additional sequence for depositing a second and a third layers, following the first, second, third or fourth sequence illustrated in FIGS. 3 to 6 (two steps 7a and 7b being illustrated);

FIG. 8 represents schematic partial-sectional views of a sequence for depositing, over a substrate, a first, a second and a third layers with through perforations (five steps 8a to 8e being illustrated);

FIG. 9 represents schematic partial-sectional views of another sequence for depositing, over a substrate, a first, a second and a third layers with through perforations (seven steps 9a to 9g being illustrated);

FIG. 10 represents schematic partial-sectional views of an additional sequence for depositing a second and a third layers, following the first, second, third or fourth sequence illustrated in FIGS. 3 to 6 (five steps 10a to 10e being illustrated), wherein FIG. 10 illustrates more specifically the implementation of interconnection steps between two adjacent cells;

FIG. 11 represents schematic partial-sectional views of a sequence for depositing, over a substrate, a first, a second and a third layers with through perforations (six steps 11a and 11f being illustrated), wherein FIG. 11 illustrates more specifically the implementation of interconnection steps between two adjacent cells;

FIGS. 12a to 12k represent schematic perspective views of a sequence for depositing, over a substrate, a first, a second and a third layers with through perforations (eight steps being illustrated, FIG. 12g being a zooming of a portion of FIG. 12f and FIG. 12k being a zooming of a portion of FIG. 12j), wherein the sequence is identical to that of FIG. 10, FIGS. 12a to 12k illustrating four cells adjacent in pairs;

FIGS. 13a and 13b are schematic views of a first paving of perforations for a photovoltaic device in accordance with the invention, with a first orthogonal or square periodic paving with four basic patterns illustrated in FIG. 13a and with a whole cell resuming these patterns in FIG. 13b;

FIGS. 14a and 14b are schematic views of a second paving of perforations for a photovoltaic device in accordance with the invention, with a second staggered or honeycomb periodic paving, with five basic patterns illustrated in FIG. 14a and with a whole cell resuming these patterns in FIG. 14b;

FIGS. 15a and 15b are schematic views of a third paving of perforations for a photovoltaic device in accordance with the invention, with a third non-periodic paving of the <<pinwheel>>-type with one basic pattern illustrated in FIG. 15a and with a whole cell resuming this pattern in FIG. 15b;

FIGS. 16a to 16c are schematic views of a fourth paving of perforations for a photovoltaic device in accordance with the invention, with a fourth non-periodic paving of the random-type, with respectively seven and four basic patterns illustrated in FIGS. 16a and 16b and with a whole cell resuming these patterns in FIG. 16c.

### DETAILED DESCRIPTION

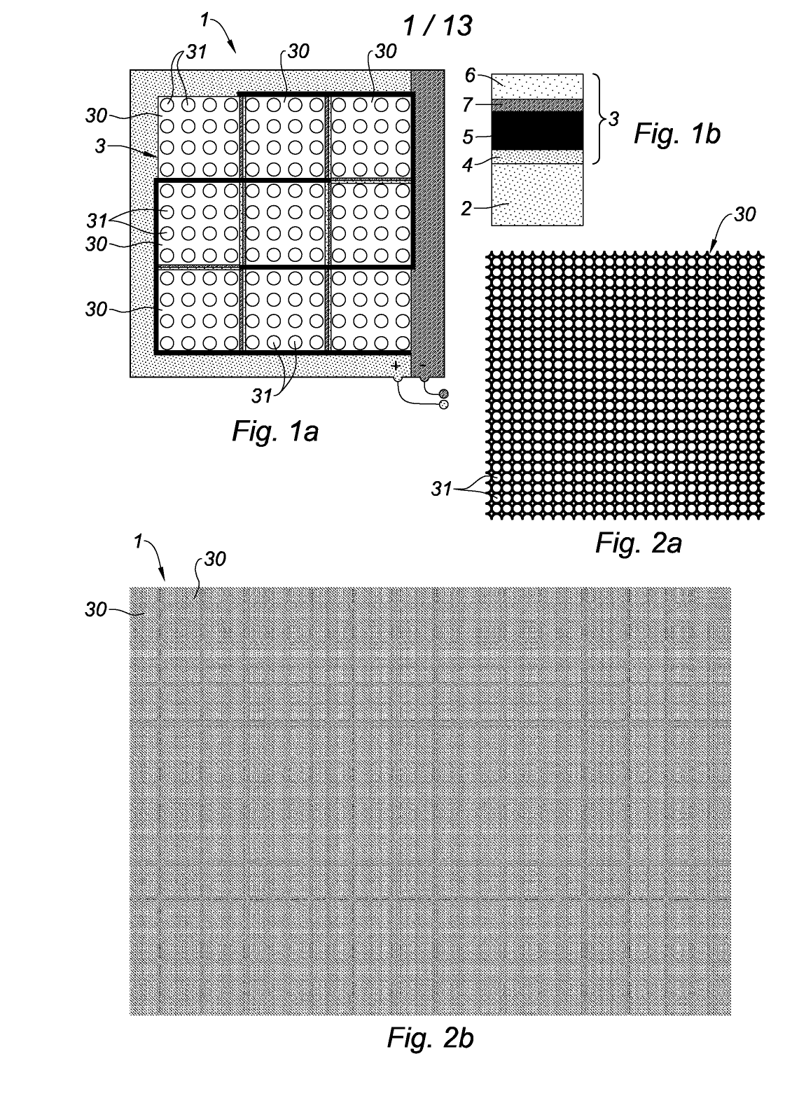

Referring to FIGS. 1a and 1b, a thin-layer photovoltaic device 1 in accordance with the invention comprises:

a substrate 2, such as a glass substrate for an application in the solar glazing; and

a photovoltaic film 3 composed of a superposition of layers distributed along a plane called main plane, and divided into a plurality of individual and interconnected photovoltaic cells 30, each cell 30 being connected in series or in parallel to one or several adjacent cell(s) 30 and insulated from the other adjacent cells.

Referring to FIG. 1b, the photovoltaic film 3 is composed of a superposition of the following successive thin layers:

a first conductive layer 4, in particular a metallic-type layer, forming a rear electrical contact deposited over the substrate;

a second photoactive layer 5 absorbing in the solar spectrum based on inorganic material, in particular based on CIGS;

a third layer 6 made of transparent conductive material, forming a front electrical contact, in particular a conductive oxide; and

optionally an intermediate thin layer 7, called window or <<buffer>> layer and in particular based on CdS, between the second and third layers 5, 6.

Each cell 30 comprises a plurality of individual perforations 31 passing through either the first and second layers 4, 5, or the first, second and third layers 4, 5, 6; these perforations 31 thereby ensuring semi-transparency of the cells 30, the perforated areas being transparent to the visible light and the non-perforated areas being opaque to the visible light.

In accordance with the invention, these perforations 31 are distributed over each cell 30 according to the following geometric conformation:

each perforation 31 presents dimensions in the main plane comprised between 10 nanometers and 400 micrometers (these dimensions corresponding to their diameters in the case of circular perforations);

each perforation 31 is distant from the nearest adjacent perforation 31 at a distance comprised between 5 nanometers and 400 micrometers;

the total surface of the perforations 31 disposed in the cell 30 taken in the main plane, is comprised between 10 and 90% of the total surface of the cell 30 in this same main plane.

Thus, each cell 30 presents a transparency comprised between 10 and 90%, depending on the total surface occupied by the perforations 31 in the concerned cell 30. The dimensions of the perforations 31 and the distances between perforations are selected so as to offer a visual comfort in accordance with the resolving power of the eye, so that the human eye distinguishes little the perforations 31 in the cells 30 and sees a substantially uniform surface.

FIG. 2a illustrates a cell 30 in which there are provided perforations 31 distributed according to a periodic paving the detail of which will be described later, and FIG. 2b illustrates a photovoltaic device 1 integrating such cells 30 and which presents a quasi-uniform aspect.

The following description is about the method for manufacturing such a photovoltaic device 1, starting from the substrate 2 over which it is desired to deposit the photovoltaic film 3 divided into perforated and interconnected cells 30; several variants may be considered.

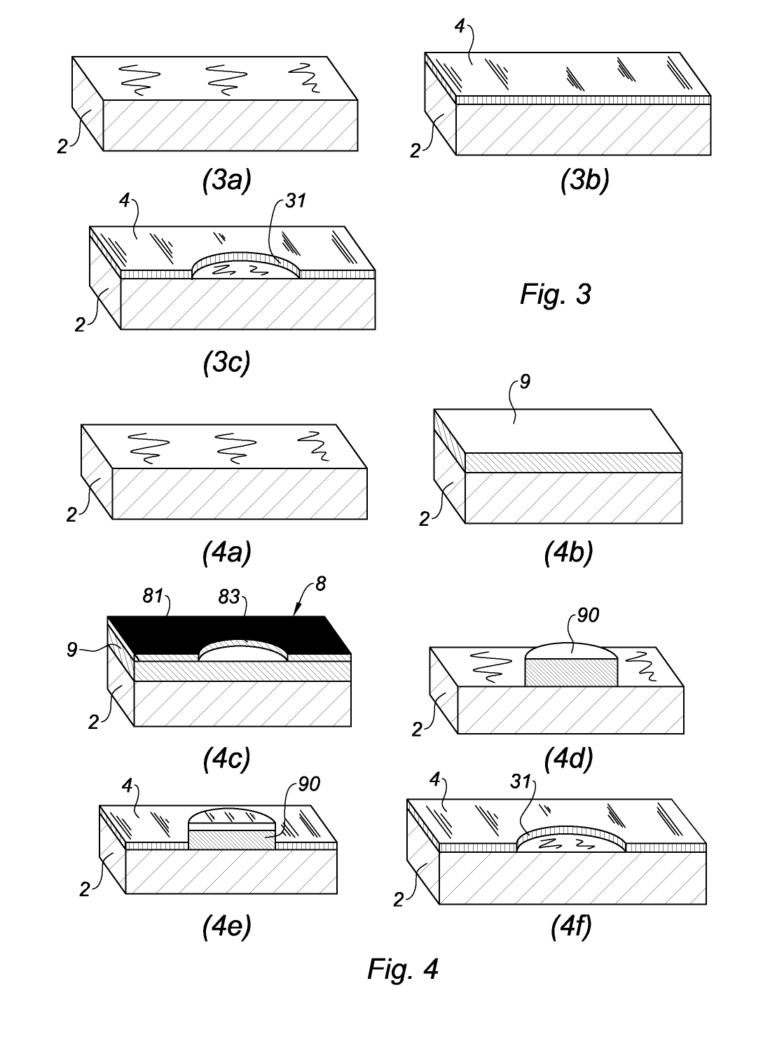

FIGS. 3 to 6 illustrate four distinct sequences allowing to make a first perforated layer 4 according to the aforementioned geometric conformation.

According to a first sequence illustrated in FIG. 3, a substrate 2 (FIG. 3a) is provided, a first uniform layer 4 is deposited over the substrate 2 by spraying or by evaporation (FIG. 3b), then through orifices, in other words the perforations 31, are directly engraved, in this first layer 4, in particular by laser engraving. The first layer 4 is engraved and hence perforated in accordance with the aforementioned geometric conformation.

According to a second, third and fourth sequences illustrated in FIGS. 4 to 6, a mask 8 is used according to a printing method, in particular of the type material-jet digital, flexography, screen-printing or pad-printing, said mask 8 presenting areas called main areas 81 defining a positive or a negative of the perforations 31.

This mask 8 will serve as a stencil which will allow to make the distribution of the perforations 31 on the first layer 4 according to the aforementioned geometric conformation, the main areas 81 of the mask 8 defining:

either a positive of the perforations 31, in other words the areas that have been obscured by the main areas 81 will ultimately correspond to the perforations 31;

or a negative of the perforations 31, in other words the areas that have not been obscured by the main areas 81 will ultimately correspond to the perforations 31;

Working by printing, the mask 8 can take the form of a masking material layer, such as ink, forming the negative or the positive of the perforations 31.

In the case of a mask 8 forming a positive of the perforations 31, the mask 8 includes, for each cell, a plurality of individual main areas 81 made of masking material, distributed over each cell according to the following geometric conformation:

each main area 81 presents dimensions in the main plane comprised between 10 nanometers and 400 micrometers (these dimensions corresponding to their diameters in the case of circular areas 81);

each main area 81 is distant from the nearest adjacent main area 81 at a distance comprised between 5 nanometers and 400 micrometers;

the total surface of the main areas 81 disposed in the cell taken in the main plane, is comprised between 10 and 90% of the total surface of the cell 30 in this same main plane.

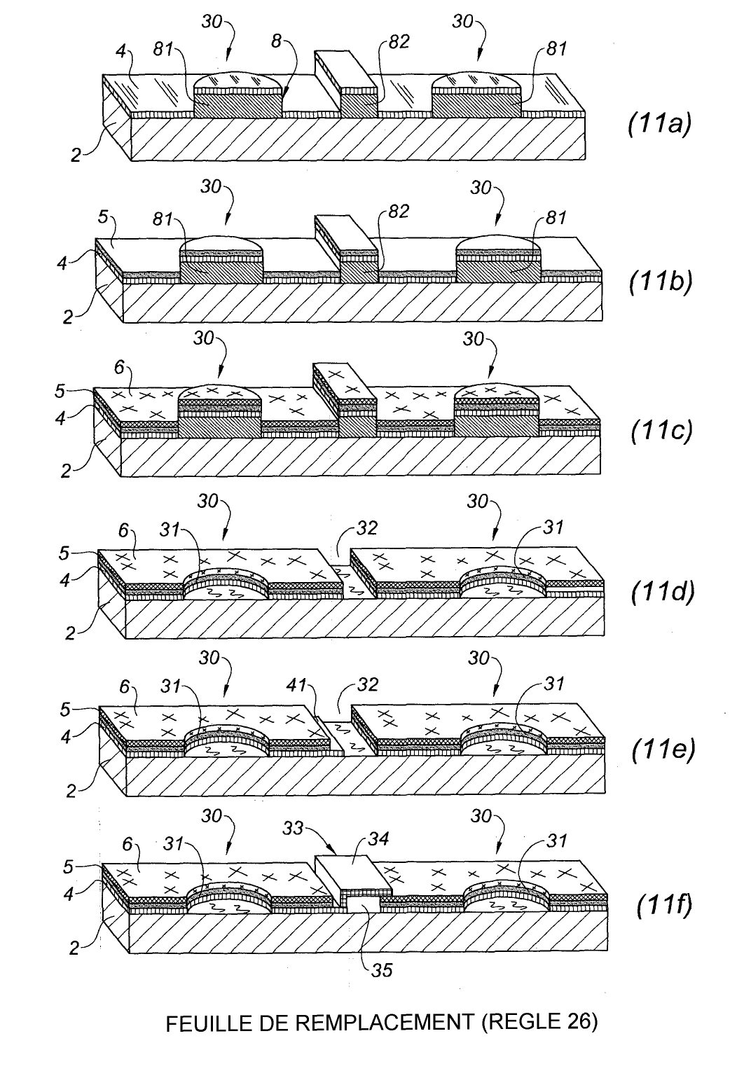

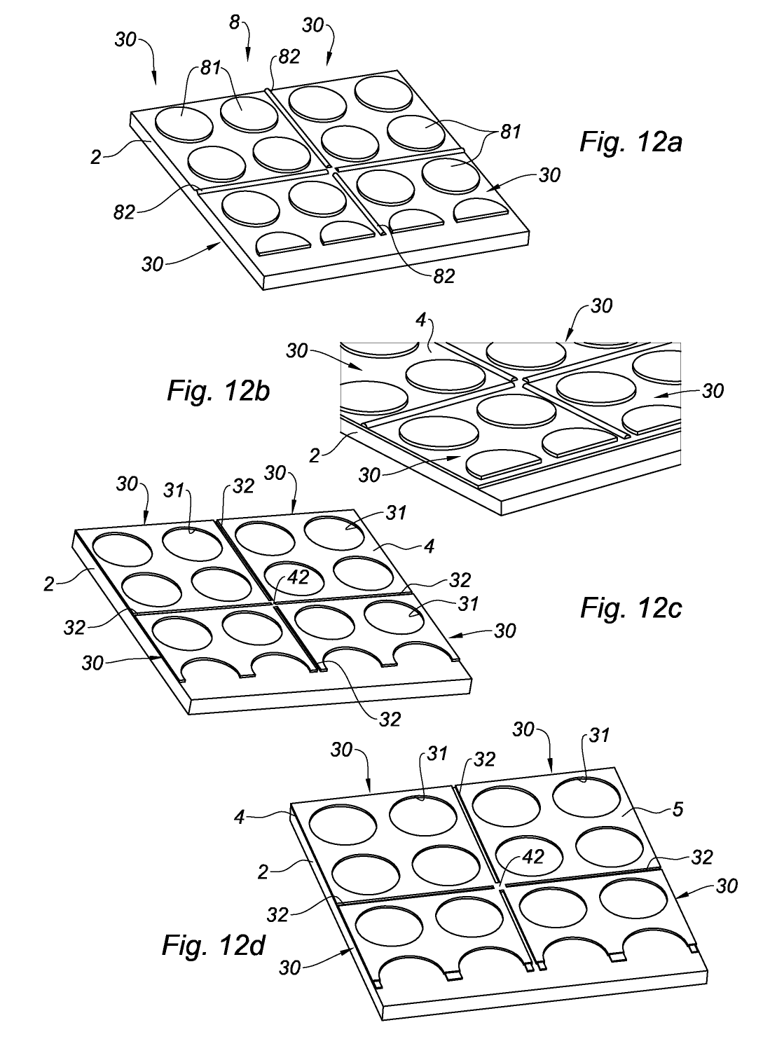

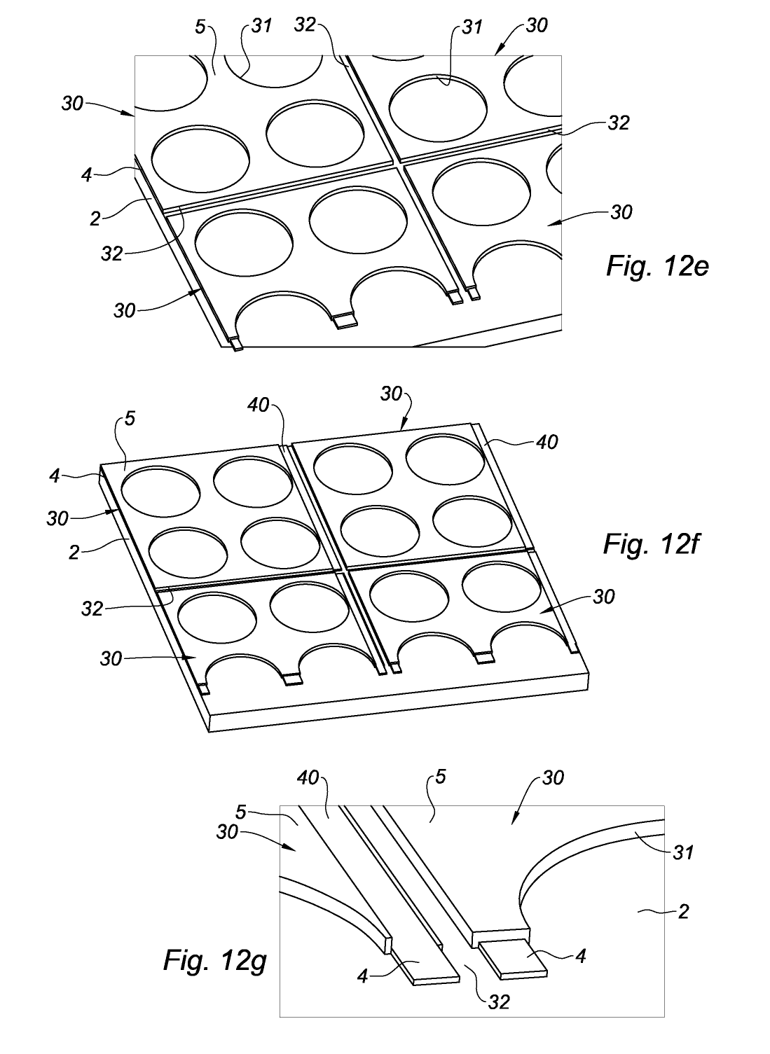

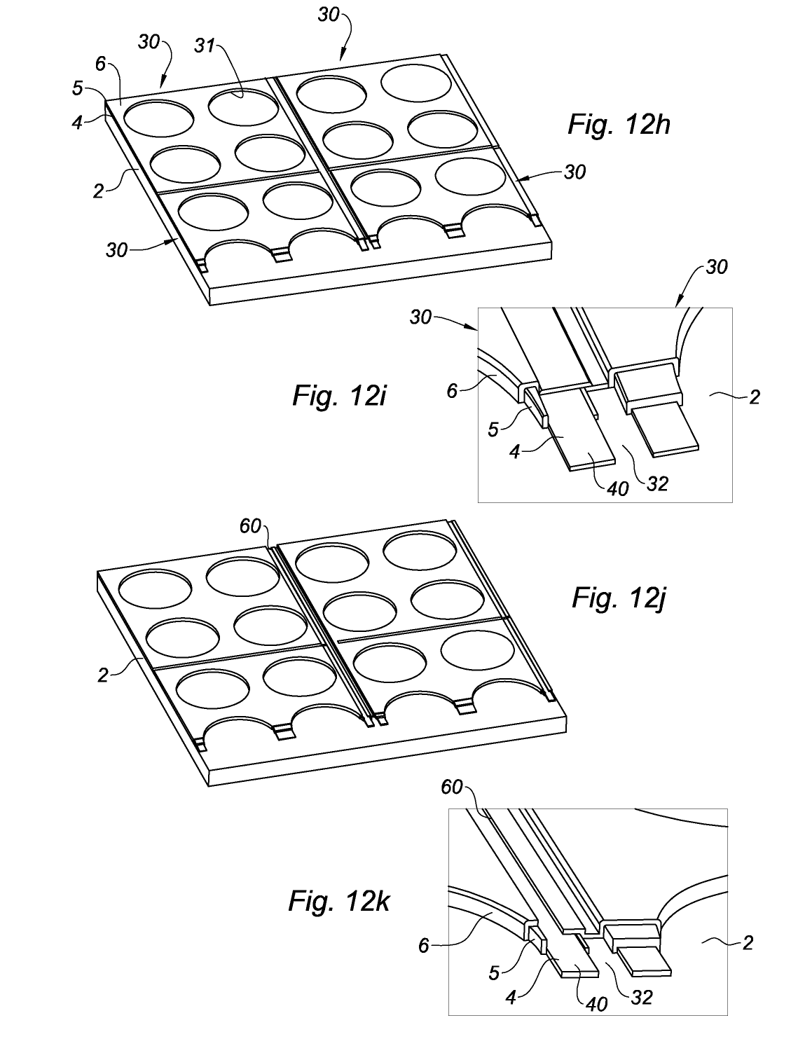

Thus, with a mask 8 forming a positive of the perforations 31, the mask 8, for each cell, is in the form of a plurality of main areas 81 spaced apart from each other (as illustrated in particular in FIG. 12a and FIGS. 13 to 16).

In the case of a mask 8 forming a negative of the perforations 31, the mask 8 includes, for each cell, contiguous main areas 81 framing individual perforations 83 distributed over each cell according to the following geometric conformation:

each perforation 83 of the mask 8 presents dimensions in the main plane comprised between 10 nanometers and 400 micrometers (these dimensions corresponding to their diameters in the case of circular perforations);

each perforation 83 of the mask 8 is distant from the nearest adjacent perforation 83 at a distance comprised between 5 nanometers and 400 micrometers;

the total surface of the perforations 83 of the mask 8 disposed in the cell taken in the main plane, is comprised between 10 and 90% of the total surface of the cell in this same main plane.

Thus, with a mask 8 forming a negative of the perforations 31, the mask 8, for each cell, is in the form of a continuous layer of masking material, in which there are provided perforations 83 spaced apart from each other (as can be seen in FIG. 4c).

In the second sequence illustrated in FIG. 4, a substrate 2 (FIG. 4a) is provided, then:

a photosensitive resin layer 9 is deposited over the substrate 2 (FIG. 4b);

the mask 8, made in a layer of opaque masking material, is deposited over the resin layer 9, this opaque mask 8 forming a negative stencil of the geometric conformation of the perforations 31 by presenting perforations 83 as described above (FIG. 4c);

the resin 9 is insolated by applying a luminous radiation, then the areas of the resin layer 9 that have not been exposed to the luminous radiation and corresponding to the areas of the resin layer 9 that have been masked by the mask 8, are chemically eliminated (by stripping), laying bare areas of the substrate and leaving in place islets of the insolated resin 90 (FIG. 4d);

a first layer 4, which covers the remaining islets of insolated resin 90 and the areas of the substrate 2 that have been laid bare, is deposited in a uniform manner, by spraying or by evaporation (FIG. 4e);

the remaining islets of insolated resin 90 are eliminated, leaving over the substrate 2 only but the first layer 4 presenting negative orifices 31 of the mask 8.

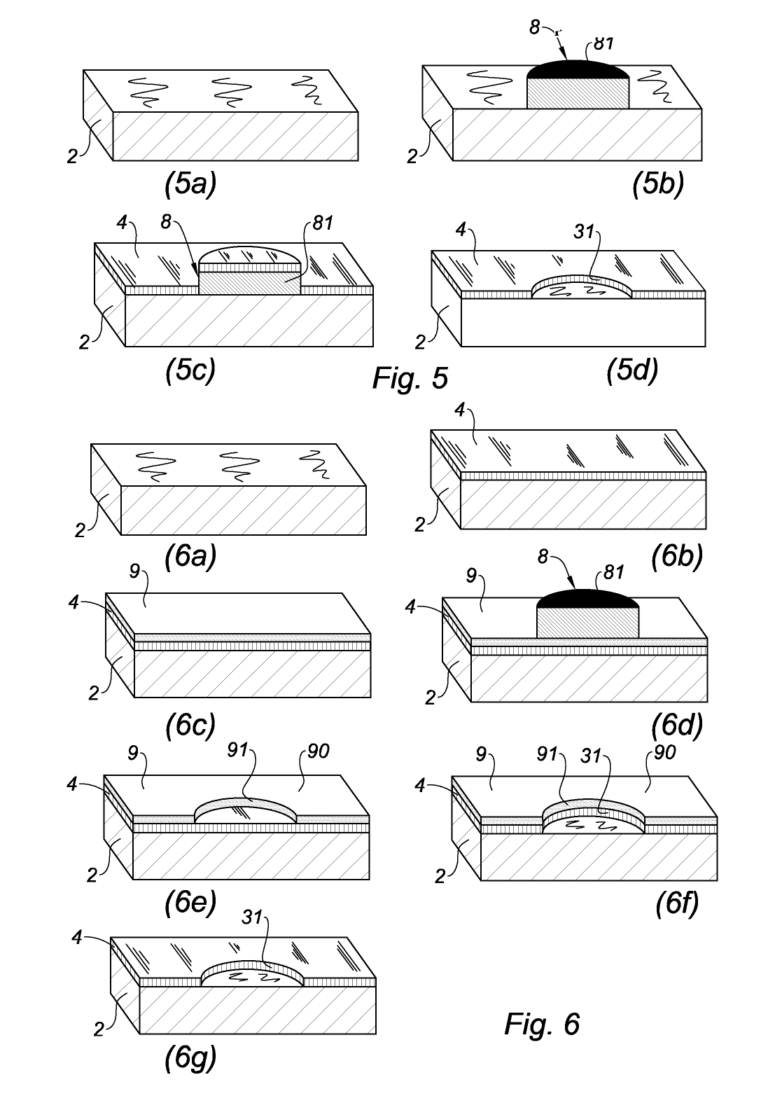

In the third sequence illustrated in FIG. 5, a substrate 2 (FIG. 5a) is provided, then:

the mask 8 is deposited over the substrate 2, this mask 8 forming a positive stencil of the geometric conformation of the perforations 31 by presenting individual main areas 81 as described above (FIG. 5b);

a first layer 4, which covers the mask 8 and the bare (not masked) areas of the substrate 2, is deposited in a uniform manner, by spraying or by evaporation (FIG. 5c);

the mask 8 is chemically eliminated, leaving over the substrate 2 only but the first layer 4 presenting positive orifices 31 of the mask 8 (FIG. 5d).

In this third sequence, the optical characteristics of the mask 8 do not matter, in other words the mask 8 may or may not be opaque. Indeed, the mask 8 is used to form a physical barrier for the deposition of the first layer 4, without making use of an insolation step.

In the fourth sequence illustrated in FIG. 6, a substrate 2 (FIG. 6a) is provided, then:

a first layer 4 is deposited over the substrate 2 in a uniform manner, by spraying or by evaporation (FIG. 6b);

a photosensitive resin layer 9 is deposited over the first uniform layer 4 (FIG. 6c);

the mask 8, made in a layer of opaque masking material, is deposited over the resin layer 9, this opaque mask 8 forming a positive stencil of the geometric conformation of the perforations 31, by presenting individual main areas 81 as described above (FIG. 6d);

the resin (9) is insolated by applying a luminous radiation through the previously deposited mask 8, and then the areas of the resin layer 9 that have not been exposed to the luminous radiation and corresponding to the areas of the resin layer 9 that have been masked by the main areas 81 of the mask, are chemically eliminated (by stripping), laying bare areas of the first uniform layer 4 and leaving in place islets of insolated resin 90 surrounding perforations 91 in the resin layer 9 (FIG. 6e);

the areas of the first layer 4 that have been laid bare, between the islets of insolated resin 90 and through the perforations 91, are eliminated by chemical engraving, thereby forming through orifices—namely the perforations 31—in the first layer 4 (FIG. 6f);

the remaining islets of insolated resin 90 on the first layer 4 are eliminated, leaving over the substrate 2 only but the first layer 4 presenting the positive perforations 31 of the mask 8 (FIG. 6g).

Starting from the end of any one of the four sequences described above with reference to FIGS. 3 to 6, there is hence obtained, over the substrate 2, a first layer 4 with perforations 31 disposed in accordance with the desired geometric conformation.

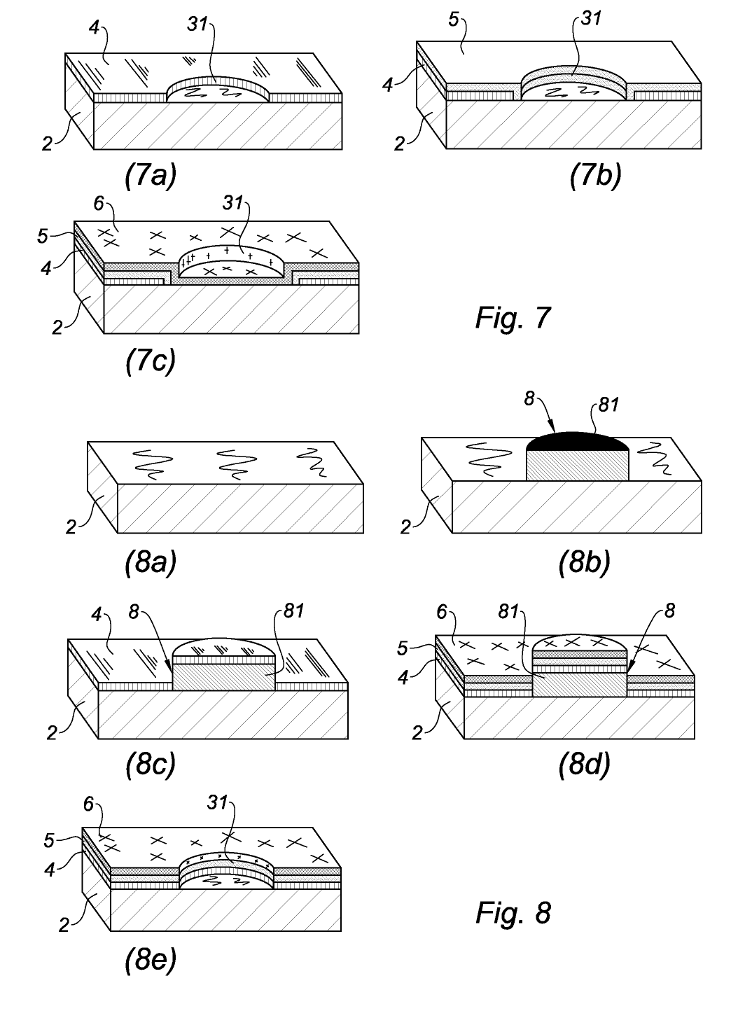

To deposit the second and third layers 5, 6 over such a first perforated layer 4, it may be considered to proceed as follows, with reference to FIG. 7:

there is disposed the substrate 2 over which the first layer 4 with the perforations 31 is deposited (FIG. 7a);

the second layer 5 is deposited by electrodeposition over the non-perforated portions of the first layer 4 (FIG. 7b), the first conductive layer 4 serving as an electrode which will attract the photoactive semi-conductive material of the second layer 5 once the first layer 4 is polarized and immersed in an electrodeposition bath, the non-polarized areas of the substrate 2 that have been laid bare being spared by the electrodeposition;

the third layer 6 is deposited by evaporation (FIG. 7c).

The deposition of the third layer 6 is carried out by evaporation, thereby covering the entire surface, including the perforations 31, which causes no prejudice because the third layer 6 is naturally transparent, furthermore, the step of electrodeposition guarantees that the second layer 5 entirely wraps the first layer 4, which prevents the third layer 6 from coming into contact with the first layer 4 and short-circuiting the cell.

In the case of the aforementioned three sequences using a mask 9, the mask 8 has been used only to make the perforations 31 in the first layer 4, before getting rid of it for proceeding with the deposition of the second layer 5 by electrodeposition.

However, it may be considered to provide variants wherein the mask 8 is preserved and removed only at the end of the process, after depositing the second and third layers 5.

In a first variant illustrated in FIG. 8, which constitutes a variant of the third sequence of FIG. 5, a substrate 2 (FIG. 8a) is provided, then:

the mask 8 is deposited over the substrate 2, this mask 8 forming a positive stencil of the geometric conformation of the perforations 31 by presenting main areas 81 as described above (FIG. 8b);

a first layer 4, which covers the mask 8 and the bare (not masked) areas of the substrate 2, is deposited in a uniform manner by spraying or by evaporation (FIG. 8c);

a second layer 5 is deposited in a uniform manner, by spraying or by evaporation, a third layer 6 is deposited in a uniform manner, by spraying or by evaporation (FIG. 8d); and

the mask 8 is chemically eliminated, leaving over the substrate 2 only but the first, second and third layers 4, 5, 6 presenting the positive perforations 31 of the mask 8 (FIG. 8e).

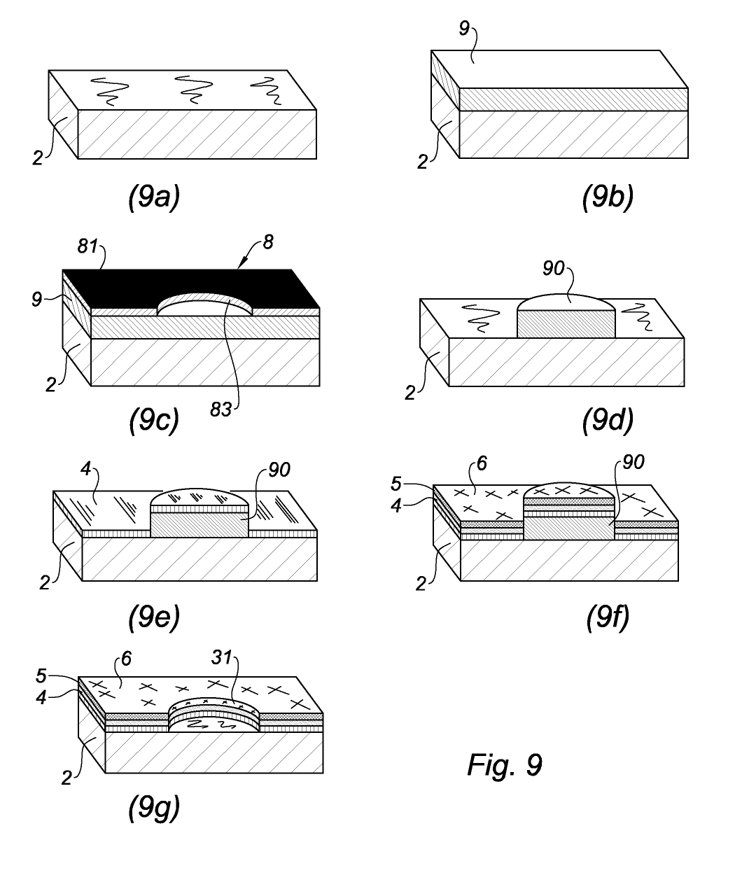

In a second variant illustrated in FIG. 9, which constitutes a variant of the second sequence of FIG. 4, a substrate 2 (FIG. 9a) is provided, then:

a photosensitive resin layer 9 is deposited over the substrate 2 (FIG. 9b);

the mask 8, made in a layer of opaque masking material, is deposited over the resin layer 9, this mask forming a negative stencil of the geometric conformation of the perforations (FIG. 9c);

the resin 9 is insolated by applying a luminous radiation, then the areas of the resin layer 9 that have not been exposed to the luminous radiation and corresponding to the areas of the resin layer 9 that have been masked by the opaque mask 8, are chemically eliminated (by stripping), laying bare areas of the substrate and leaving in place islets of insolated resin 90 (FIG. 9d);

a first layer 4, which covers the remaining islets of insolated resin 90 and the areas of the substrate 2 that have been laid bare, is deposited in a uniform manner, by spraying or by evaporation (FIG. 9e);

a second layer 5 is deposited in a uniform manner, by spraying or by evaporation, then a third layer 6 is deposited in a uniform manner, by spraying or by evaporation (FIG. 9f); and

the remaining islets of insolated resin 90 are eliminated, leaving over the substrate 2 only but the first, second and third layers 4, 5, 6 presenting the negative perforations 31 of the mask 8 (FIG. 9g).

In these two variants, the third layer 6 does not cover the perforations 31, because the mask 8 is removed after placing this third layer 6, thereby avoiding short-circuit between the first and third layers 4, 6.

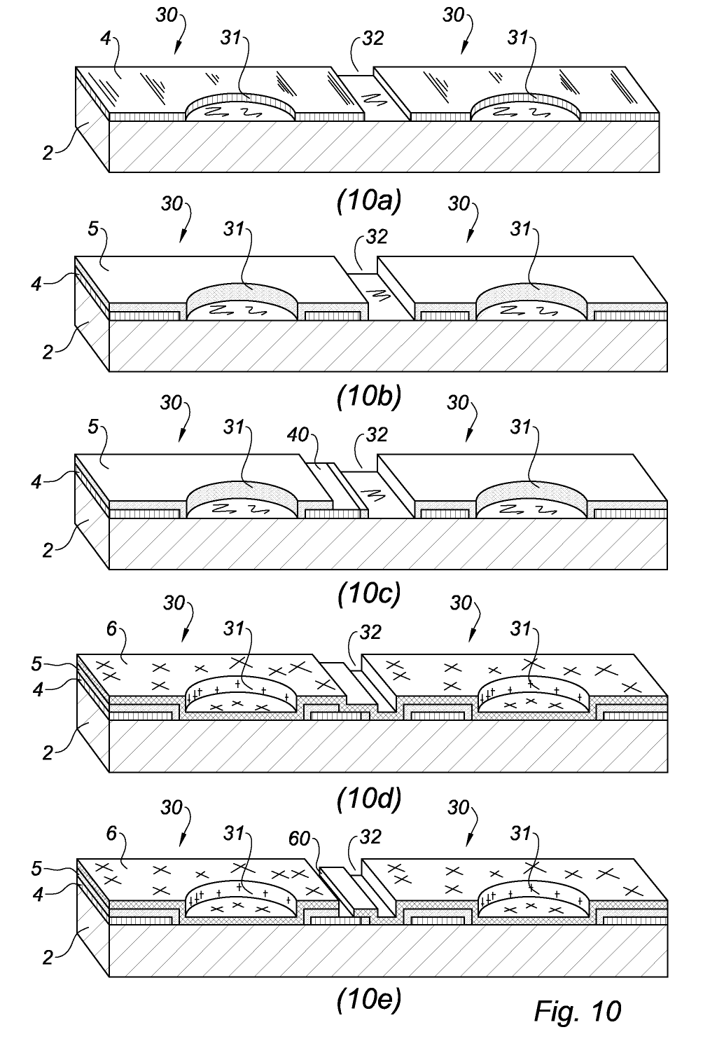

The following description is about the division of the photovoltaic film into several cells, and about the interconnection between two adjacent cells, with reference to FIGS. 10 to 12.

FIGS. 10 and 12 illustrate an improvement of the steps of FIG. 7, by focusing on the sub-steps intended to ensure the interconnection between two adjacent cells 30, in other words the electrical connection between the first layer 4 of a cell 30 and the third layer 6 of an adjacent cell 30.

FIGS. 10a and 12c illustrate each a substrate 2 over which a first layer 4 is deposited, with two cells 30 (FIG. 10a) or four cells 30 (FIG. 12c) separated by respective separating strips 32. Each separating strip 32 electrically separates the first layer 4 of a cell 30 from the first layer 4 of an adjacent cell 30.

Several embodiments of the separating strips 32 may be considered, being specified that a separating strip 32 constitutes a perforated groove or a notch in the first layer 4. Thus, the separating strip 32 is made in the same manner as the perforations 31.

In a first embodiment, the separating strip 32 is made by direct engraving, in the same manner as in the first sequence illustrated in FIG. 3.

In a second embodiment, the separating strip 32 is made from a mask which presents secondary areas 82 defining a positive or a negative of the separating strips 32 between the cells, that is to say:

either a positive as in the third and fourth sequences of FIGS. 5 and 6, the secondary areas 82 then being in the form of strips 82 which delimit the cells 30;

or a negative as in the second sequence of FIG. 4, the secondary areas 82 framing slots which delimit the cells 30 and which pass through the layer of the mask 8;

FIG. 12a illustrates the application of a positive mask 8 directly over the substrate (as in the third sequence illustrated in FIG. 5) with the main 81 and secondary 82 areas. Note that the secondary areas 82 are not joined at the intersection between the four cells 30.

FIG. 12b then illustrates the uniform application of the first layer 4 over the substrate 2 and the mask 8.

FIG. 12c illustrates the step of chemically eliminating the mask 8, leaving over the substrate 2 only but the first layer 4 presenting the perforations 31 and the separating strips 32. Note that the first layers 4 of all cells 30 are electrically connected because the secondary areas 82 are not joined, leaving an electrical contact 42 between these cells 30 after removal of the mask 8. This electrical contact 42 between the cells 30 aims to facilitate the step of electrodepositing the second layer 5, because it is sufficient to polarize one of the cells 30 to have all cells 30 polarized in an equivalent manner.

Starting from the first layer 4 with the perforations 31 and the separating strips 32, the following steps are carried out to deposit the second and third layers 5, 6, while ensuring interconnection between the two cells 30:

the second layer 5 is deposited by electrodeposition, over the non-perforated portions of the first layer 4 (FIG. 10b and FIG. 12d), this step is facilitated because the first layers 4 of all cells are electrically connected together thanks to the electrical contact 42;

the first and second layers 4, 5 are engraved so as to cut the electrical contact 42 between the cells 30, at the ends of the separating strips 32 (FIG. 12e);

the second layer 5 is directly engraved (FIGS. 10c, 12f and 12g), in particular according to a technique called <<scribing>> technique, over one or several cell(s) 30, along an edge of the concerned separating strip 32 (the left edge in FIGS. 10c, 12f and 12g), along a given width, laying bare strips 40 of the first layer 4 of the cells 30, these strips 40 being parallel to the separating strips 32 (in FIG. 12f, only the strips 40 between cells on the left and on the right are illustrated, but not those between the cells on the top and on the bottom);

the third layer 6, which thus covers the second layer 5 in a uniform manner, is deposited by evaporation, the bare strips 40 of the first layer 4 of the first cell 30, the perforations 31 and the separating strips 32 (FIGS. 10d, 12h and 12i—the third layer 6 not illustrated in the perforations 31 in FIGS. 12h to 12k for clarity), so that an electrical contact is made between the strips 40 and the third layer 6, but with short-circuits at the cells 30;

the third layer 6 is directly engraved, in particular according to a technique called <<scribing>> technique, so as to cut the aforementioned short-circuits established in the cells 30 on their respective strips 40 (FIGS. 10e, 12j and 12k), by engraving strips 60 over this third layer 6 so as to lay bare a portion of the strips 40 of the first layer 4 of the cells 30 (cutting the electrical contact between the first and the third layers 4, 6 within the same cell 30), while keeping an electrical contact between the strips 40 of a cell and the third layer 6 of the adjacent cell, thereby establishing the series connection between the cells 30.

It is to be noted that, if the second layer 5 is deposited by evaporation or spraying (instead of the deposition by electrodeposition illustrated in FIGS. 10b and 12d), it is no longer necessary to ensure the prior electrical contact 42 between the cells 30. Thus, in this case, the secondary areas 82 of the mask 8 may be joined.

FIG. 11 illustrates an improvement of the steps of FIG. 8, focusing on sub-steps intended to ensure the interconnection between two adjacent cells 30, in other words the electrical connection between the first layer 4 of a cell 30 and the third layer 6 of an adjacent cell 30.

FIG. 11a illustrates a substrate 2 over which a positive mask 8 has been deposited presenting main 81 and secondary 82 areas, and over which a first layer 4 has been deposited afterwards in a uniform manner, by spraying or by evaporation.

Starting from the situation of FIG. 11a, the following steps are carried out to deposit the second and third layers 5, 6, while ensuring interconnection between the two cells 30:

a second layer 5 is deposited in a uniform manner, by spraying or by evaporation (FIG. 11b);

a third layer 6 is deposited in a uniform manner, by spraying or by evaporation (FIG. 11c);

the mask 8 is chemically eliminated, leaving over the substrate 2 only but the first, second and third layers 4, 5, 6 presenting the positive perforations 31 of the main areas 81 and the positive separating strips 32 of the secondary areas 82 (FIG. 11d);

the second and third layers 5, 6 are directly engraved, in particular according to a technique called <<scribing>> technique, along an edge of the separating strip 32, along a given width (left edge in FIG. 11e), in order to lay bare a strip 41 of the first layer 4 of the first cell 30, this strip 41 being parallel to the separating strip 32 (FIG. 11e);

there is provided, in the separating strip 32, an electrical contactor 33 which comprises a conductive portion 34 establishing contact between the strip 41 and the third layer 6 of the second cell 30 and an insulating portion 35 interposed between the first layers 4 of the two cells 30, thereby establishing the series connection between the two cells 30.

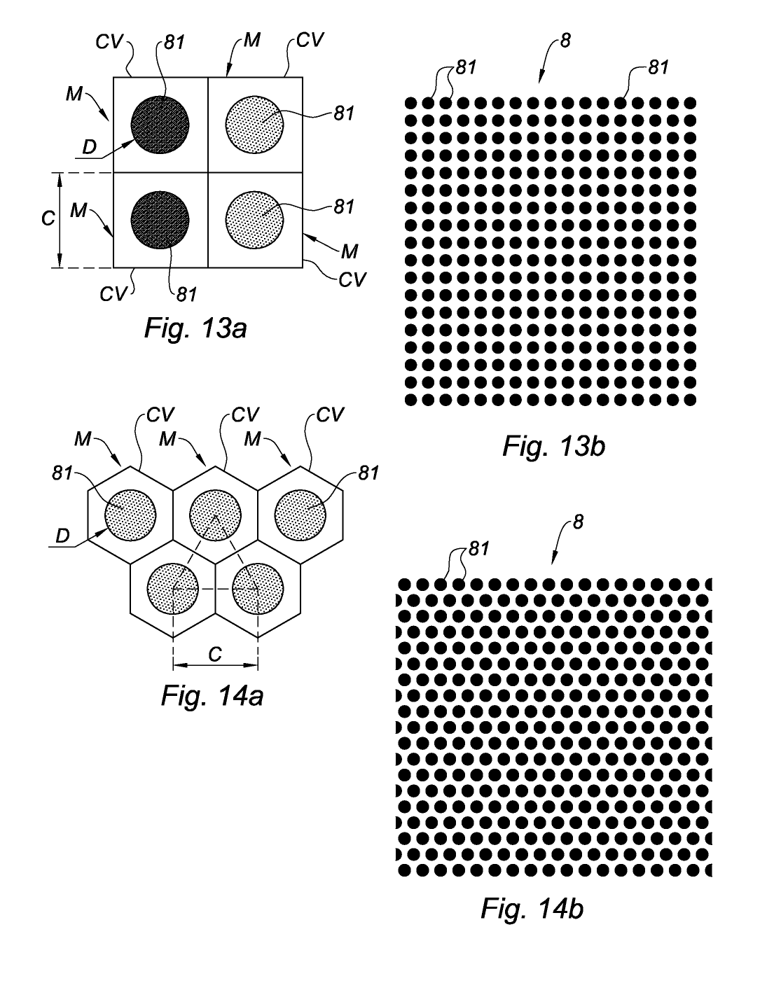

The following description is about the geometric conformation of the perforations 31, in particular with reference to FIGS. 13 to 16.

In accordance with the invention, the perforations 31 are distributed over the surface of each cell 30 according to a virtual paving composed of a plurality of elementary photovoltaic units, juxtaposed without void and without encroachment so as to define the corresponding cell 30. The principle is thus to define one or several basic pattern(s), defining one or several elementary unit(s), which will be repeated so as to entirely pave each cell 30, so that by managing transparency at the microscopic level (with the elementary units), transparency is managed at the macroscopic level (at the cell).

Each elementary unit is in the form of a geometric portion of the photovoltaic film 3, the dimensions of which in the main plane are comprised between 15 nanometers and 800 micrometers, delimited by a virtual outline (the outline of the pattern) and to which there is associated at least one perforation arranged in whole or in part inside said outline (the perforated surface in the elementary unit microscopically defining the perforated surface of the cell), each perforation being associated to one single elementary unit.

Each elementary unit presents a perforated surface, corresponding to the surface of the perforation(s) associated to the elementary unit in the main plane, which is comprised between 10 and 90% of the total surface of the elementary unit in this same main plane, preferably between 30 and 70%.

By working with a mask 8, paving of the elementary units is managed by managing paving of the above described main areas 81.

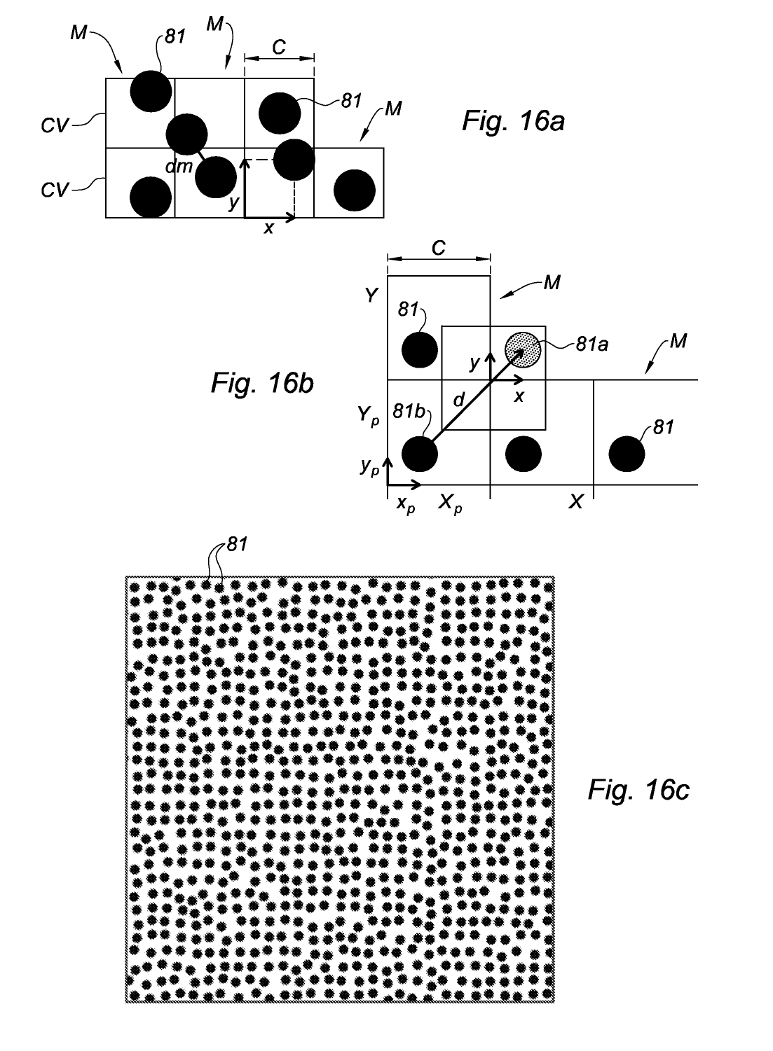

FIGS. 13 and 16 illustrate positive masks 8 presenting circular-shaped main areas 81 (other shapes may of course be considered) distributed according to predefined paving.

With a positive mask 8, the main areas 81 of the mask 8 are distributed over the surface of each cell 30 according to a virtual paving composed of a plurality of patterns M juxtaposed without void and without encroachment, each pattern M being delimited by a virtual outline CV to which there is associated at least one main area 81 located in whole or in part inside said outline CV.

The pattern M forms the smallest geometric element that allows constructing the mask 8 at a macroscopic scale by applying a given algorithm to this pattern M (mainly a translation along two directions, a symmetry and a rotation), while integrating that the pattern M should preferably offer the least interaction with the physiological mechanisms of the vision, and contribute to the best perceived uniformity of the photovoltaic device as well as to the best visual comfort.

Furthermore, it is important to note the following definition: the resolution of the mask 8 characterizes the smallest dimension of the basic pattern. However, the resolution has no impact on the level of transparency or on the energy efficiency of the photovoltaic film, but it may influence the way the eye perceives the transparency of this photovoltaic film and thus this resolution constitutes a potential factor of visual comfort or discomfort. In particular, the resolution intervenes on the perceived uniformity of the photovoltaic film, and the finest the resolution is, the more the perception of uniformity will be important.

In the implementation of a method for printing the mask 8, it is to be noted that the resolution of the mask 8 is still downwardly limited by the used printing technique. As an illustration, if the printing method presents an intrinsic resolution of 300 points per inch for drawing the pattern, this means that the basic printed point is in the order of at least 85 micrometers, so that such a printing method will not allow drawing patterns that are smaller than 100 micrometers. Hence, the intrinsic resolution of the method for printing the mask 8 automatically conditions the final resolution of the mask 8.

In a first embodiment of the mask 8 illustrated in FIGS. 13a and 13b, a periodic paving is implemented from a pattern M consisting of a concentric disc (the main area 81) centered inside a square (the virtual outline CV), so that:

the disc 81 defines the perforation 31 (that is to say the perforated and thus transparent surface of the elementary photovoltaic unit); and

the portion of the pattern inscribed in the square and surrounding the disc 81 defines the opaque and active area of the elementary photovoltaic unit.

Hence, the level of transparency of the pattern (and thus of the cell 30 at the macroscopic level) is characterized by the ratio of the surface of the disc 81 to the surface of the square CV that contains it. The pattern M is repeated by translation along axes parallel to the sides of the square C, thereby creating alignments of the discs along these two axes.

The resolution of the pattern M is characterized by the length C of the side of the square CV. Depending on the desired level of transparency T, with T comprised between 0 and 1 (0 for full opacity and 1 for full transparency), it would be possible to calculate the diameter D of the disc 81 using the following formula:

D=2C·(T/π)^{1/2}

For reasons inherent to the technology, the active area of the associated elementary photovoltaic unit should remain connected, so that the diameter of the disc should remain lower than the length C, which allows deducing an upper limit of the achievable transparency rate with such a pattern M which is π/4, namely a maximum transparency of about 78.5%.

In practice, it will be necessary to take into account the capabilities of the printing method that is implemented to create the space between two neighboring discs 81, thereby reducing the value of the maximum transparency that is actually accessible.

Furthermore, the lower limit of the transparency rate is also determined by the implemented printing method, and more specifically by the minimum size of the printable point that the method allows to achieve, the smallest disc being then reduced to one single point.

In a second embodiment of the mask 8 illustrated in FIGS. 14a and 14b, a periodic paving is implemented from a pattern M consisting of a concentric disc (the main area 81) centered inside a hexagon (the virtual outline CV).

In this manner, a staggered or honeycomb paving is implemented, the discs 81 of a line (or of a column) being placed in a staggered manner relative to those of the preceding line (or column), while imposing that all discs 81 are equidistant.

This hexagonal pattern M is defined by two quantities:

the length C of the equilateral triangle side formed by the centers of three non-aligned immediately adjacent discs 81 (in other words, the spacing between two immediately adjacent discs 81), which determines the resolution of the mask 8; and

the diameter D of the discs 81.

Thus, the mask 8 is constructed by paving the plane using this pattern M and, as previously explained with the square pattern, the level of transparency is adjusted by the ratio of the surface of the disc 81 to the surface of the hexagon CV, according to the following formula which gives the diameter D of the disc 81 for a given transparency T:

D=C·[(2T·3^{1/2})/π]^{1/2}

As in the preceding case with the square pattern, the active area of the associated elementary photovoltaic unit should remain connected, which means that the value of the diameter D cannot exceed the value of the aforementioned length C, which allows deducing therefrom an upper limit of the achievable transparency rate with such a pattern M which is π/(2.3^{1/2}) namely a maximum transparency of about 90.7%.

In order to avoid having periodic patterns which could reduce the visual comfort of the photovoltaic film, it may be considered to proceed with a non-periodic paving of the plane, so as to in the end distribute the perforations over the surface of each cell in a non-periodic manner (in other words in a non-regular manner).

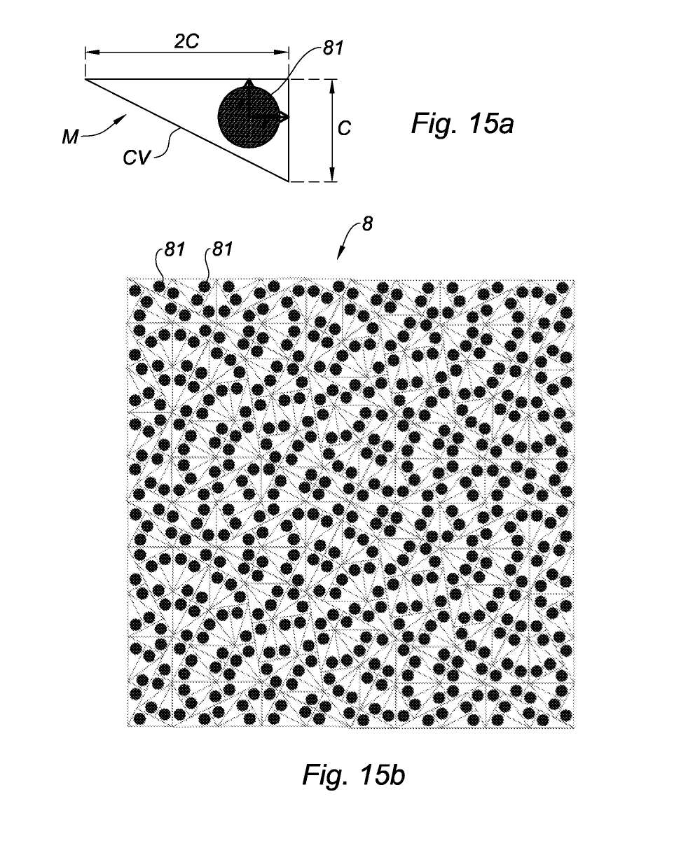

In a third embodiment of the mask 8 illustrated in FIGS. 15a and 15b, a non-periodic paving called <<pinwheel>> non-periodic paving is implemented. This paving is made from a pattern M composed of a concentric disc (the main area 81) located inside a right-angled triangle (the virtual outline CV) the catheti of which are in a ratio of two, with one cathetus of a length C and another cathetus of a length 2C.

As an example, the concentric disc 81 is centered on the point of intersection of the bisectors of the triangle, with a center located at an equal distance r from the catheti, r corresponding to the radius of the inscribed circle, namely:

r=C·(3−5^{1/2})/4

The <<pinwheel>> paving, developed by the British mathematician John Conway, is based on a decomposition of the considered triangle into five homothetic triangles from an original triangle, by the implementation of symmetries, translations and rotations.

As previously described with the first and second paving, the level of transparency is given by the ratio of the surface of the disc 81 to the surface of the triangle CV, thereby allowing calculating the diameter D of the disc 81 as a function of the transparency T according to the following formula:

D=2C·(T/π)^{1/2}

The maximum transparency is obtained when the diameter D of the disc is equal to the diameter of the inscribed circle, namely D=r, which allows deducing that the maximum transparency is about 45.8%.

In a fourth embodiment of the mask 8 illustrated in FIGS. 16a to 16c, a non-periodic paving of the random-type is implemented, so as to in the end distribute the perforations over the surface of each cell in a random manner (a random distribution being a particular case of the non-periodic distribution).

This random paving constitutes an variant of the non-periodic paving exposed above, with the aim of breaking periodicity, that is to say not obtaining parallel and regularly distributed lines of perforations (for example in the form of disc); the principle being to scramble the distribution of the perforations so that the eye cannot catch on any regular structure.

However, this random paving should comply with some constraints and statistical properties.

The first constraint consists in that the paving of the patterns should ensure a constant level of transparency which is independent of the considered scale (unless, of course, falling below the basic pitch). In other words, this random paving should not lead to obtain too significant transparent or opaque areas so that the overall rendering is relatively uniform.

The second constraint comprises keeping a minimum distance between two neighboring discs 81, so as to be able to guarantee a deposition of the first layer 4 with a minimum width (depending on the capabilities of the printing technology of the mask 8 and/or the deposition technology of the thin layers) between two perforations 31.

As an example of a random paving, consider a pattern M based on a square CV with a side C. The transparency of the pattern M is created by inserting one single disc 81 for each square CV, the ratio of the surface of the disc 81 to the surface of the square CV providing the level of transparency, as already calculated above.

However, unlike the periodic paving where the disc 81 is centered on the square CV, it is only required that the center of the disc 81 is located within the perimeter of the square CV by randomly drawing its location for each basic pattern M.

Thus, by defining the coordinates (x, y) of the center of the disc 81 and by placing the origin of the coordinate system in the lower-left corner of each square CV, the following first system of constraints is thus obtained: x belongs to the interval [0, C] and y belongs to the interval [0, C].

As a reminder, the aforementioned second constraint focuses on the distance separating two discs 81. Indeed, this second constraint aims at preventing two neighboring discs 81 from overlapping, and even at guaranteeing some thickness of the line of the first layer 4 between two discs. Hence, this second constraint results in a minimum distance dm between the centers of two neighboring discs.

The following parameters are defined, with reference to FIG. 16b:

X and Y the order numbers of the pattern of which the coordinates of the center (x, y) of the disc 81 should be drawn;

Xp and Yp the order numbers of the pattern relative to which the distance should be guaranteed; and

xp and yp the coordinates of the center of the corresponding disc.

The disc 81a of FIG. 16b is the disc to be positioned relative to the previously placed disc 81b. The distance d between this disc 81a and the preceding disc 81b is the hypotenuse of a right-angled triangle with sides [(X−Xp)·C+x−xp] and [(Y−Yp)·C+y−yp] and.

This distance d should be larger than the imposed distance dm, so that the following relationship is obtained for the second constraint:

[(X−Xp)·C+x−xp]²+[(Y−Yp)·C+y−yp]²>dm²

Moreover, it is to be noted that dm should not be larger than the side C, otherwise it won't be possible to construct the model at a larger scale. Indeed, in this case, the discs would be statistically more spaced from each other than the pitch of the pattern, implying that after a while it would no longer be possible to house the center of the disc inside the associated square.

Moreover, in order to avoid a too high local dispersion of the characteristics which would disturb the pattern at a large scale, it is desirable to compell the discs not to be too far away from each other, for example by imposing that the components x (respectively y) of two neighboring discs located on the same horizontal line do not differ of more than 1.5·C (respectively 0.5·C), the same for neighboring discs located on a same vertical line. These values 1.5·C and 0.5·C are given as an indicative example.

FIG. 16c illustrates a random paving over a cell built according to the aforementioned constraints.

In general, other shapes of the main areas 81 may be considered, not only the disc shape, as for example elliptical, rectangular shapes, etc. The use of these other shapes might turn out to be interesting in particular for non-periodic paving, where the orientation of the basic pattern varies. As an example, an elliptical-shaped main area in a <<pinwheel>> paving would allow to access higher levels of transparency and contribute to visually scramble the pattern by varying the angle of the focal axis of the ellipse with the horizontal.

Furthermore, it may be considered to vary the dimensions of the main areas 81 over the substrate, in order to offer a gradient effect, for example, with a transparency that gradually increases from the bottom to the top or from the right to the left over the substrate.

Of course, the aforementioned example of implementation is in no way limiting and other improvements and details may be brought to the photovoltaic device according to the invention, without departing from the scope of the invention where other pattern shapes can, for example, be made.

1. A thin-layer photovoltaic device comprising a substrate on which there is disposed a photovoltaic film composed of a superposition of layers distributed along a plane called main plane and comprising at least a first conductive layer forming a rear electrical contact, a second photoactive layer absorbing in the solar spectrum based on inorganic material, a third layer made of transparent conductive material forming a front electrical contact, said photovoltaic film being divided so as to form a plurality of individual and interconnected photovoltaic cells, each cell being connected in series or in parallel to one or several adjacent cell(s) and electrically insulated from the other adjacent cells,
said device comprising a plurality of individual perforations passing through at least the first and the second layers of the photovoltaic film in each cell, each perforation presenting dimensions in the main plane comprised between 10 nanometers and 400 micrometers, each perforation being distant from the nearest adjacent perforation at a distance comprised between 5 nanometers and 400 micrometers, and in that each cell presents a perforated surface, corresponding to the surface of the perforations disposed in said cell in the main plane, which is comprised between 10 and 90% of the total surface of the cell in this same main plane, preferably between 30 and 70%.

2. The photovoltaic device according to claim 1, wherein the perforations are distributed over the surface of each cell according to a non-periodic distribution, in particular according to a non-periodic paving.

3. The photovoltaic device according to claim 2, wherein the perforations are distributed over the surface of each cell according to a random distribution, in particular according to a random paving.

4. The photovoltaic device according to claim 1, wherein the perforations are distributed over the surface of each cell according to a periodic distribution, in particular according to a periodic paving.

5. The photovoltaic device according to claim 1, wherein the perforations are distributed over the surface of each cell according to a virtual paving composed of a plurality of elementary photovoltaic units, juxtaposed without void and without encroachment, so as to define the corresponding cell, each elementary unit being in the form of a geometric portion of the photovoltaic film delimited by a virtual outline and to which there is associated at least one perforation arranged in whole or in part inside of said outline, each perforation being associated to one single elementary unit, and wherein each elementary unit presents a perforated surface, corresponding to the surface of the perforation(s) associated to said elementary unit in the main plane, which is comprised between 10 and 90% of the total surface of the elementary unit in this same main plane, preferably between 30 and 70%.

6. The photovoltaic device according to claim 5, wherein each elementary unit presents dimensions in the main plane comprised between 10 and 800 micrometers.

7. The photovoltaic device according to claim 2, wherein the elementary units are distributed over the surface of each cell according to a non-periodic paving, and wherein the elementary units are identical in the shape and the dimensions of the virtual outline as well as in the conformation, the number and the dimensions of the perforation(s) associated to each elementary unit.

8. The photovoltaic device according to claim 2, wherein the elementary units are distributed over the surface of each cell according to a periodic paving, and wherein the elementary units are identical in the shape and the dimensions of the virtual outline but distinct in the conformation, the number and/or the dimensions of the perforation(s) associated to each elementary unit.

9. The photovoltaic device according to claim 4, wherein the elementary units are distributed over the surface of each cell according to a periodic paving, and the elementary units are identical in the shape and the dimensions of the virtual outline as well as in the conformation, the number and the dimensions of the perforation(s) associated to each elementary unit.

10. The photovoltaic device according to claim 1, wherein the substrate is constituted of a glass substrate.

11. The photovoltaic device according to claim 1, wherein the first layer is an opaque metallic layer directly in contact over the substrate.

12. A method for manufacturing a photovoltaic device in accordance with claim 1, wherein:
a photovoltaic film is disposed over a substrate by the superposition of layers distributed along a plane called main plane and comprising at least a first conductive layer forming a rear electrical contact, a second photoactive layer absorbing in the solar spectrum and based on inorganic material, and a third layer made of transparent conductive material forming a front electrical contact;
the photovoltaic film is divided into a plurality of individual and interconnected photovoltaic cells, each cell being connected in series or in parallel with one or several adjacent cell(s) and electrically insulated from the other adjacent cells,
said method comprising a plurality of individual perforations passing through at least the first and second layers of the photovoltaic film in each cell, in compliance with the following geometric characteristics:
each perforation presents dimensions in the main plane comprised between 10 nanometers and 400 micrometers,
each perforation is distant from the nearest adjacent perforation at a distance comprised between 5 nanometers and 400 micrometers,
each cell presents a perforated surface, corresponding to the surface of the perforations disposed in said cell in the main plane, which is comprised between 10 and 90% of the total surface of the cell in this same main plane, preferably between 30 and 70%.

13. The method according to claim 12, wherein the perforations are distributed over the surface of each cell according to a non-periodic distribution, in particular according to a non-periodic paving.

14. The method according to claim 13, wherein the perforations are distributed over the surface of each cell according to a random distribution, in particular according to a random paving.

15. The method according to claim 12, wherein the perforations are distributed over the surface of each cell according to a periodic distribution, in particular according to a periodic paving.

16. The method according to claim 12, wherein the following steps are performed:
a first conductive layer is made with through orifices disposed in accordance with the geometric characteristics of the perforations;
the second layer is deposited over the non-perforated portions of the first conductive layer, preferably by electrodeposition;
the third layer is deposited, preferably by evaporation.

17. The method according to claim 16, wherein a first uniform conductive layer is deposited over the substrate then the through orifices are engraved in said first conductive layer, in particular by laser engraving.

18. The method according to 12, wherein a mask is deposited according to a printing method, in particular a digital-type printing method by material jet, flexography, screen-printing or pad-printing, said mask presenting main areas defining a positive or a negative of the perforations made at least in the first layer.

19. The method according to claim 16, wherein
a first uniform conductive layer is deposited over the substrate;
a photosensitive resin layer is deposited over the first uniform conductive layer;
the mask is deposited over the resin layer, said mask forming a positive stencil of the geometric conformation of the perforations;
the resin is insolated by applying a luminous radiation through the previously deposited mask;
the areas of the resin layer that have not been exposed to the luminous radiation and corresponding to the areas of the resin layer that have been masked by the mask, are eliminated, laying bare areas of the first uniform conductive layer and leaving in place islets of insolated resin;
the areas of the first conductive layer that have been laid bare, between the islets of insolated resin, are eliminated, thereby forming through orifices in said first conductive layer;
the islets of insolated resin remaining on the first conductive layer are eliminated, thereby leaving over the substrate only but the first conductive layer presenting positive orifices of the mask.

20. The method according to claim 18, wherein:
a photosensitive resin layer is deposited over the substrate;
the mask is deposited over the resin layer, said mask forming a negative stencil of the geometric conformation of the perforations;
the resin is insolated by applying a luminous radiation;
the areas of the resin layer that have not been exposed to the luminous radiation and corresponding to the areas of the resin layer that have been masked by the mask, are eliminated, laying bare areas of the substrate and leaving in place islets of insolated resin;
a first conductive layer, which covers the remaining islets of insolated resin and the areas of the substrate that have been laid bare, is deposited in a uniform manner.

21. The method according to claim 16, wherein, following the deposition of the first conductive layer, the remaining islets of insolated resin are eliminated, leaving over the substrate only but the first conductive layer presenting negative orifices of the mask.

22. The method according to claim 20, wherein, following the deposition of the first conductive layer:
the second layer, which covers the first conductive layer, is deposited in a uniform manner;
the third layer, which covers the second layer, is deposited in a uniform manner;
the remaining islets of insolated resin are eliminated, leaving over the substrate the photovoltaic film presenting negative perforations of the mask 8.

23. The method according to claim 18, wherein:
the mask is deposited over the substrate, said mask forming a positive stencil of the geometric conformation of the perforations;
a first conductive layer, which covers the mask and the bare areas of the substrate, is deposited in a uniform manner.

24. The method according to claim 16, wherein, following the deposition of the first conductive layer, the mask is eliminated, leaving over the substrate only but the first conductive layer presenting positive orifices of the mask.

25. The method according to claim 23, wherein, following the deposition of the first conductive layer:
the second layer, which covers the first conductive layer, is deposited in a uniform manner;
the third layer, which covers the second layer, is deposited in a uniform manner;
the mask is eliminated, leaving over the substrate the photovoltaic film presenting positive perforations of the mask.

26. The method according to 18, wherein the mask presents secondary areas defining a positive or a negative of the separating strips between the cells of the photovoltaic film.
